(19) United States
(12) Patent Application Publication
(10) Pub. No.: US 2011/0163393 A1
(43) Pub. Date: Jul. 7, 2011

(54) SEMICONDUCTOR DEVICE MANUFACTURING METHOD AN INTEGRATED CIRCUIT COMPRISING SUCH A DEVICE

(75) Inventor: Robert J. P. Lander, Leuven (BE)

(73) Assignee: NXP B.V., Eindhoven (NL)

(21) Appl. No.: 12/997,439

(22) PCT Filed: May 20, 2009
(86) PCT No.: PCT/IB09/52126

§ 371 Date: Mar. 10, 2011

(30) Foreign Application Priority Data
Jun. 11, 2008 (EP) 08104376.2
May 20, 2009 (IB) PCT/IB2009/052126

(51) Int. Cl. H01L 27/04; H01L 21/283

(52) U.S. Cl. 257/401; 438/592; 257/E27.01; 257/E21.159

(57) ABSTRACT

A method of manufacturing a semiconductor device on a substrate (10) is disclosed. The method comprises providing the substrate (10) including a body region (12) protruding from said substrate (10), the body region (12) being covered by a gate electrode material (16, 56) forming a first gate region (18) on a first side of the body region (12) and a second gate region (20) on a second side of the body region (12), the gate material (16, 56) being separated from the body region (12) by a dielectric layer (14); and introducing a dopant (22, 58) of a first conductivity type into the gate electrode material (16, 56) such that the first gate region (18, 20) is exposed to the dopant while the second gate region (20, 18) is substantially sheltered from the dopant by the protruding body region (12). This allows for versatile tuning of the work function of a single gate to be formed. An integrated circuit comprising such a semiconductor device is also disclosed.

The present invention relates to a method of manufacturing a semiconductor device comprising providing a substrate including a body region protruding from said substrate, the body region being covered by a gate electrode material forming a first gate region on a first side of the body region and a second gate region on a second side of the body region, the gate material being separated from the body region by a dielectric layer.

The present invention further relates to a semiconductor device comprising a substrate including a gate structure comprising a body region protruding from said substrate, the body region being covered by a gate comprising a first gate region on a first side of the body region and a second gate region on a second side of the body region and being separated from the body region by a dielectric layer.

The ongoing downscaling of the feature sizes of semiconductor devices such as transistors has caused the alteration of the three-dimensional shape of such devices in order to be able to provide smaller devices that are capable of meeting performance requirements. For instance, in order to overcome detrimental short channel effects (SCE) such as off-state leakage current caused by the downscaling of the channel length in reduced feature size technologies, the concept of the FinFET has been proposed, which is a transistor that has a body region protruding from the silicon substrate, with the body region being covered by one or more gate electrodes electrically insulated from the body region by a gate dielectric. Such devices benefit from an elongated channel length formed at the surfaces of the body region compared to traditional transistor designs having a horizontal channel region at the substrate surface, thus giving better control over SCE and giving improved current characteristics.

However, the use of FinFETs is not without problems. For instance, the use of high-k dielectrics as gate dielectric may require the introduction of a metal as the gate electrode, which has a completely different work function than a polycrystalline silicon (poly-Si) gate electrode. This for instance has an impact on the leakage current of the semiconductor device. Moreover, ICs including different functional blocks may require different types of semiconductor devices to meet the different performance requirements of the different functional blocks. For instance, the combination of a FinFET for an SRAM functional block and a planar bulk device for core logic is complicated by the very different gate work function requirements of the two functionalities. Planar bulk requires a band edge work function, which is close to n⁺ doped Si for NMOS devices and close to p⁺ doped Si for PMOS devices, whereas fully depleted FinFETs require close to mid-gap work function, especially for applications with low static leakage such as SRAMs. The mid-gap work function cannot be achieved by poly-Si gates, which requires the introduction of metal gate electrodes.

The integration of different work function electrodes in a single integrated circuit can be costly and complex, especially when it has to be combined with the integration of intermediate dielectric capping layers or other multi layer solutions that involve selective patterning before complete metal stack deposition. Hence, there exists a need to provide a method that allows for a more facile tuning of a gate electrode work function.

WO2008/026859 discloses a FinFET having multiple electrically connected gate electrodes each enveloping the protruding body region. The gate electrodes have different work functions achieved by different impurity doping types in different electrodes, such that a gate electrode at the source side of the FinFET has a different work function than a gate electrode at the drain side of the FinFET.

U.S. Pat. No. 6,853,020 discloses a FinFET having separate electrode structures on opposite sides of the fin. The separate electrode structures have different work functions, which have been achieved by the formation of spacers on either side of the fin, and selectively doping the spacers with an n-type and a p-type dopant respectively by introducing the dopants under an angle of 30° with the substrate such that only the targeted spacer is predominantly doped with the dopant. The spacers are subsequently covered by polycrystalline silicon (poly-Si) to form separate gates at either side of the fin.

However, it is not always required or even desirable to have a bulk region covered by multiple gates. For instance, in case of a semiconductor device having a protruding bulk region covered by a single gate, it may be difficult to achieve the desired work function for the single gate.

The present invention seeks to provide a method of manufacturing a semiconductor device for which the effective work function of a gate over a protruding body region can be more flexibly tuned.

The present invention further seeks to provide such a semiconductor device.

According to an aspect of the present invention, there is provided a method of manufacturing a semiconductor device on a substrate comprising providing the substrate including a body region protruding from said substrate, the body region being covered by a gate electrode material forming a first gate region on a first side of the body region and a second gate region on a second side of the body region, the gate material being separated from the body region by a dielectric layer; and introducing a dopant of a first conductivity type into the gate electrode material such that the first gate region is exposed to the dopant while the second gate region is substantially sheltered from the dopant by the protruding body region.

This has the advantage that only a part of the gate is implanted with a dopant such as an n-type dopant or a p-type dopant, which means that the effective work function of the gate becomes the average of the regional work function of the doped region and the regional work function of the undoped region. This allows for accurate tuning of the work function of a single gate enveloping the bulk region of the semiconductor device such as a FinFET. The dopant may be selectively introduced under a non-perpendicular angle with the substrate, which may for instance be in the range of 40-50°. This is particularly advantageous for tuning the work function of a metal gate to a midgap work function.

In an embodiment, the method further comprises introducing a further dopant of a second conductivity type into the gate electrode material such that the second gate region is exposed to the dopant while the first gate region is substantially sheltered from the dopant by the protruding body region. This is particularly advantageous for tuning the effective work function of a poly-Si gate to a midgap work function, and has the additional advantage that the work function can be tuned over an even wider range since the effective work function of the gate achieved by the average of the regional work functions of the two regions can now be composed of more extreme regional work function values.

At this point, it is emphasized that although implanting n and p type dopants under an angle in respective spacers of different gates is known from U.S. Pat. No. 6,853,020, this prior art document does not teach or even suggest that the work function of a single gate can be tuned by identifying different regions in a single gate and differently doping the different regions such that the single gate has an effective work function that is composed of the average of the regional work functions, i.e. the work functions of the different regions. In other words, the present invention is based on the realization that a gate can be composed of different regional work functions at a microscopic level while still maintaining an overall uniform behavior. In contrast, the cited prior art documents teach the formation of gates that only have a single region in terms of work function tuning.

In an embodiment, the substrate comprises a first area including the body region, and a second area for forming a further semiconductor device, the method further comprising masking the second area prior to said dopant introducing step, and removing said mask after said dopant introducing step. This way, areas of different functionality and/or different device geometry can be selectively targeted when adjusting work functions in accordance with the present invention.

The gate material may be a poly-Si material, which may at least partially silicided in a further processing step by depositing a suitable metal over the poly-Si and exposing the metal-covered poly-Si to a suitable thermal budget. It will be appreciated that by providing a single poly-Si gate with n-type and p-type doping regions on either side of the body region, a poly-Si gate is achieved that has an effective (i.e. average) mid-gap work function typically associated with metal gate electrodes.

Alternatively, the gate metal may be a metal such as a n-type metal, of which the work function may be locally adjusted by the introduction of a p-type dopant in the first gate region of the gate. The gate metal may be subsequently processed by the deposition of a poly-Si layer over the gate metal to provide a gate contact. This way, a metal electrode of one conductivity type may be converted, after its deposition, into a metal electrode of the opposite conductivity type by the selective introduction of a doping profile of the opposite conductivity type on one side of the body region.

In accordance with a further aspect of the present invention, there is provided an integrated circuit comprising a substrate carrying a semiconductor device comprising a body region protruding from said substrate, the body region being covered by a gate comprising a first gate region on a first side of the body region and a second gate region on a second side of the body region and being separated from the body region by a dielectric layer, wherein the gate comprises a dopant of a first conductivity type, said dopant being predominantly located in the first gate region.

Such a semiconductor device benefits from an improved tunability of the effective work function of the gate over the bulk region, thereby improving the control over the leakage current of the semiconductor device.

In an embodiment, the gate further comprises a further dopant of a second conductivity type, said further dopant being predominantly located in the second region, which further improves the tunability of he gate work function, as previously explained.

In a preferred embodiment, the integrated circuit comprises a first functional block comprising the semiconductor device and a second functional block comprising a further semiconductor device, the further semiconductor device comprising a further body region protruding from said substrate, the further body region being covered by a further gate being separated from the further body region by a further dielectric layer, wherein the further gate has a different work function than the gate. The first functional block may for instance be an SRAM having fully depleted FinFETs controlled by gates with a mid-gap work function, whereas the second functional block may for instance comprise digital logic having planar bulk devices having gates that exhibit band edge work functions.

The integrated circuit may be integrated in an electronic device, with the electronic device, e.g. a mobile communication device, a consumer electronics device, an automotive device and so on, benefitting from the improved work function characteristics of the semiconductor devices of the integrated circuit.

Embodiments of the invention are described in more detail and by way of non-limiting examples with reference to the accompanying drawings, wherein:

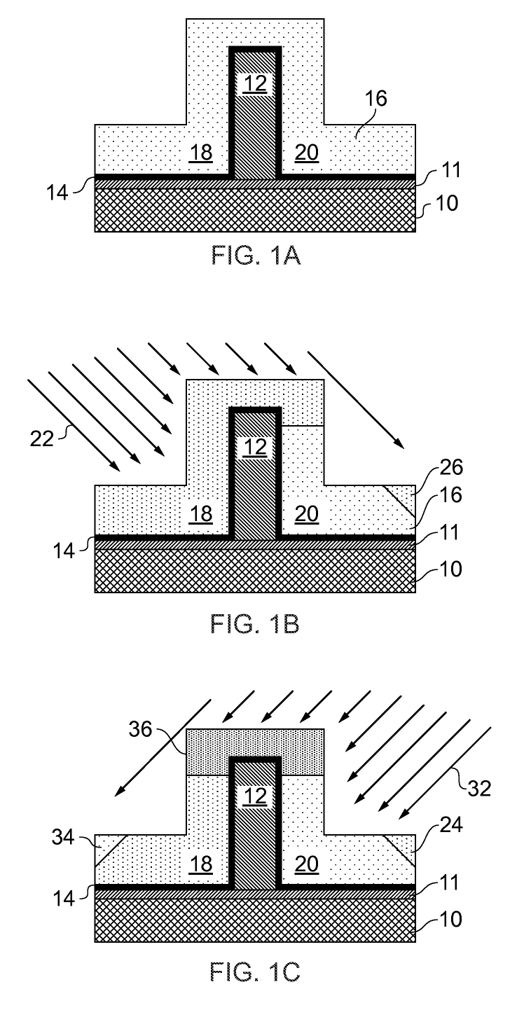

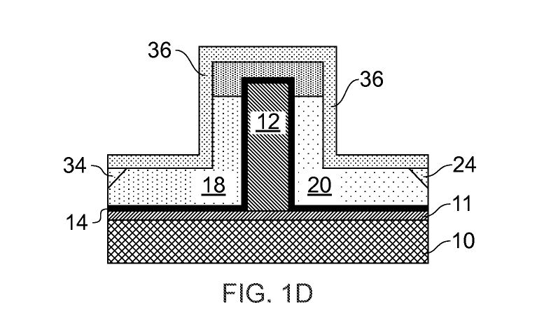

FIGS. 1a-d depict a first embodiment of the method of the present invention; and

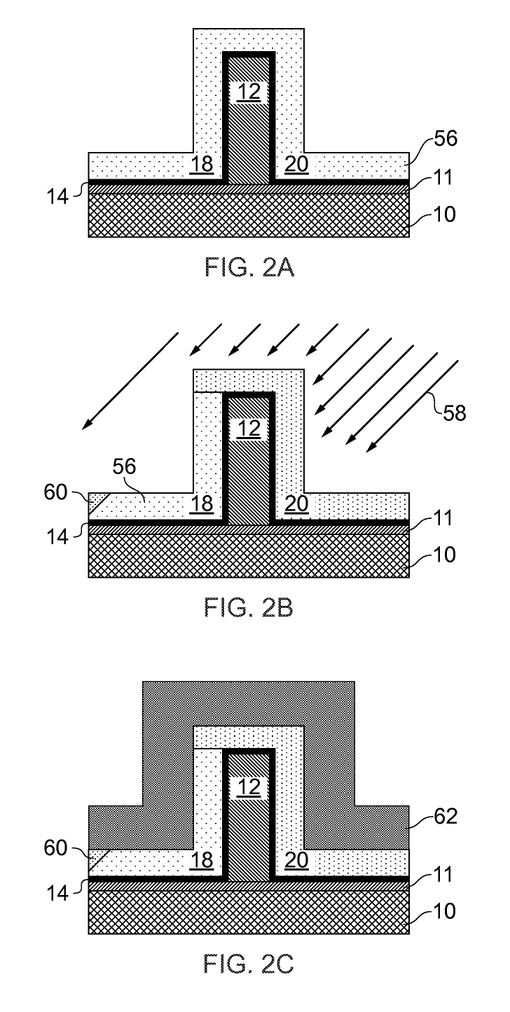

FIGS. 2a-c depict a second embodiment of the method of the present invention.

It should be understood that the Figures are merely schematic and are not drawn to scale. It should also be understood that the same reference numerals are used throughout the Figures to indicate the same or similar parts.

In FIG. 1a, a substrate 10 is provided that carries a body region 12 covered by a dielectric layer 14 and a gate material 16 such as poly-Si. In a preferred embodiment, the body region 12 is the fin of a FinFET. For instance, the fin may extend into the substrate 10 when the substrate 10 comprises a shallow trench insulation layer surrounding the fin or may be mounted on a buried oxide layer 11 of the substrate. The specific implementation of the fin is not relevant to the present invention, and may be any known implementation. In general, the provision of the above structure may be achieved in many ways well-known to the skilled person, with the exact way chosen not being essential to the present invention. For instance, the substrate 10 may form part of a SOI wafer, a single crystalline silicon wafer, and so on, whereas the dielectric layer 14 may be formed by any suitable dielectric material such as SiO₂ or a low-k dielectric material.

The gate material 16 comprises a first region 18 on a first side of the body region 12 and a second region 20 on an opposite side of the body region 12. In a next step, as shown in FIG. 1b, an impurity 22 is introduced in an angled doping step such that only one of the two regions 18, 20 is significantly implanted with the impurity. In FIG. 1b, the second region 20 does not receive a significant amount of impurity 22 because it is shaded by the height of the body region 12. It will be appreciated that the height and width of the body region 12 will have an impact of the size of the shaded region 20.

The impurity is of a conductivity type opposite to the conductivity type of the semiconductor device to be formed, e.g. a p-type implant 22 for an NMOS FinFET, and is implanted prior to the gate patterning to avoid counter-doping the source and drain regions of the semiconductor device with the impurity 22. In other words, in this doping step, the gate material 16 extends over the source and drain regions (not shown) of the semiconductor device to be formed to protect the source and drain regions from the opposite conductivity type impurity.

Depending on the implantation angle used for the doping step, an area 26 beyond the second region 20 will also receive an implant of the impurity 22. However, this does not affect the performance of the gate to be formed over the body region 12, because the area 26 is far removed from the body region 12 and may even be removed in a subsequent gate patterning step.

As shown in FIG. 1c, a second impurity 32 is predominantly introduced in second region 20 by an angled doping step. A small region 34 on the opposite side of the body region 12 may also be implanted, but this region does not affect the work function of the gate to be formed and may even be subsequently removed as already explained for region 24.

The second impurity typically is of the same conductivity type as the conductivity type of the semiconductor device to be formed, e.g. a n-type impurity 32 is used for an NMOS FinFET. This means that the introduction of the second impurity 32 does not necessarily have to be performed before the gate patterning. Alternatively, the introduction of the second impurity 32 may for instance be combined with the formation of the lightly doped drain (LDD) or highly doped drain (HDD) junction formation after gate patterning.

A combination of a partial implant into the second region 20 prior to the gate patterning and a further implant during the LDD and HDD formation is also feasible. Consequently, a gate over the body region 12 is obtained that has an asymmetric doping profile formed by the different types of impurities 22 and 32. After implantation of the impurity 22 and/or the impurity 32, the dopants are typically activated by means of an anneal step, which may be combined with an anneal step e.g. for activating source and drain implants. Alternatively, the anneal step for activating the impurity 22 and/or the impurity 32 may be a dedicated anneal step.

The gate will typically comprise a third region 36 on top of the body region 12 that comprises both impurities 22 and 32, as a consequence of the angled implantation steps. The regions 18, 20 and 36 will exhibit different work functions, e.g. with the effective work function of the gate being defined by the combination of these different regional work functions. The regional work functions can be tuned by the choice of impurity as well as the impurity concentration to be implanted in the regions 18 or 20. The effective work function may be comprised of more than three regional work functions; for instance, the angled impurity implant may be chosen such that the sidewalls of the protruding body region 12 have lower impurity concentrations than the planar regions adjacent to these sidewalls. Also, more than one type of impurity may be introduced in a region to provide further control over the tuning of the effective work function.

In an embodiment, the implanted impurity concentrations are in excess of 10¹⁹/cm³ for the n-type or p-type impurities because such concentrations effectively shift the regional work functions to the band edges.

At this point, it is emphasized that the implantation angle of the impurities 22 and 32 may be varied depending on the implantation depth requirements, dimensions of the body region 12, e.g. fin width and height, and so on. For instance, a range of 30-60° for the implantation angle may be feasible, with a preferred range of 40-50°. The implantation of the first impurity 22 and the second impurity 32 may be performed at the same angle or at different angles. Moreover, the implantation of one of the first impurity 22 and the second impurity 32 may be omitted such that an asymmetrically implanted gate having only a single region including an impurity is obtained.

It is further emphasized that although not explicitly shown in FIGS. 1a-c, the implantation of the impurities 22 and/or 32 may be applied to a selected part of the substrate 10, e.g. a part of the substrate corresponding with a functional block to be formed, such as a functional block requiring low standby current leakage because for such functional blocks, FinFET devices are particularly suitable. An example of such a functional block is an embedded SRAM. To this end, other parts of the substrate, e.g. further regions in which other types of functional blocks are to be formed and for which no adjustment or a different adjustment of the gate work function is required, may be protected from the implantation steps, e.g. by masking the further regions prior to the implantation step(s) and removing such a mask after the implantation step to facilitate further processing of the substrate 10 including these further regions.

The gate over the body region 12 may be completed using conventional processing steps. For instance, as shown in FIG. 1D, the gate material 16 is at least partially converted into a silicide 36 in order to provide a gate contact, after which the at least partially silicided gate material may be patterned to form the gate. Silicidation of a poly-Si gate material is a well-known technique to the skilled person, and will not be explained in further detail for reasons of brevity only. In an embodiment, the poly-Si is covered by Ni and subsequently converted into a NiSi silicide 36. The substrate 10 may subsequently be subjected to further conventional processing steps to complete the manufacture of an integrated circuit of the present invention.

The present invention may also be applied to metal gates over a protruding body region 12. This embodiment is shown in FIGS. 2a-c. In FIG. 2a, a substrate 10 carrying a protruding body region 12 covered by a dielectric layer 14 and a gate material 56 is provided. As previously discussed, the substrate 10 may be any suitable substrate formed in any suitable way. The metal 56 may be a p-type work function metal which work function is partially converted into an n-type work function by the angled implantation of an n-type impurity 58 into a region such as region 20 of the metal 56, with the opposite region being sheltered from the implantation by the body region 12. The implantation step may be combined with implantation steps in other regions of the substrate 10, such as the formation of an n-type gate of a planar bulk NMOS device.

The formation of a small n-type region 60 on the sheltered p-type side of the metal 56 may also take place but this region is far removed from the body region 12 and does not affect the work function of the gate to be formed. Moreover, the region 60 may be removed in a subsequent gate patterning step.

Alternatively, the metal 56 may be a n-type work function metal, which work function is partially converted into a p-type work function by the angled implantation of an p-type impurity 58 into a region such as region 20 of the metal 56. Such conversions are well-known to the skilled person and will not be discussed in further detail for reasons of brevity only.

In general, the impurity 58 introduced into part of the metal 56 by the angled implantation step is of a conductivity type opposite to the conductivity type of the metal 56.

The gate over the body region 12 may be completed using conventional processing steps. For instance, as shown in FIG. 2c, a poly-Si layer 62 may be grown over the partially implanted metal 56 to provide a gate contact, after which the gate stack is patterned and the gate is formed. The substrate 10 may subsequently be subjected to further conventional processing steps to complete the manufacture of an integrated circuit of the present invention.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The mere fact that certain measures are recited in mutually different dependent claims does not indicate that a combination of these measures cannot be used to advantage.

1. A method of manufacturing a semiconductor device on a substrate comprising:
providing the substrate including a body region protruding from said substrate, the body region being covered by a gate electrode material forming a first gate region on a first side of the body region and a second gate region on a second side of the body region, the gate material being separated from the body region by a dielectric layer; and
introducing a dopant of a first conductivity type into the gate electrode material such that the first gate region is exposed to the dopant while the second gate region is substantially sheltered from the dopant by the protruding body region.

2. A method according to claim 1, wherein the dopant is introduced under a non-perpendicular angle with the substrate.

3. A method according to claim 2, wherein the substrate comprises a first area including the body region, and a second area for forming a further semiconductor device, the method further comprising:
masking the second area prior to said dopant introducing step, and
removing said mask after said dopant introducing step.

4. A method according to claim 1, further comprising introducing a further dopant of a second conductivity type into the gate electrode material such that the second gate region is exposed to the dopant while the first gate region is substantially sheltered from the dopant by the protruding body region.

5. A method according to claim 4, wherein the further dopant is introduced under a further non-perpendicular angle with the substrate.

6. A method according to claim 1, wherein the gate electrode material is polycrystalline silicon.

7. A method according to claim 6, further comprising at least partially converting the doped polycrystalline silicon into a silicide.

8. A method according to claim 1, wherein the gate electrode material is a metal.

9. A method according to claim 8, further comprising covering the doped metal with a polycrystalline silicon layer.

10. An integrated circuit having a substrate carrying a semiconductor device comprising a body region protruding from said substrate, the body region being covered by a gate comprising a first gate region on a first side of the body region and a second gate region on a second side of the body region, the gate being separated from the body region by a dielectric layer, wherein the gate comprises a dopant of a first conductivity type, said dopant being predominantly located in the first gate region.

11. An integrated circuit according to claim 10, wherein the gate further comprises a further dopant of a second conductivity type, said further dopant being predominantly located in the second gate region.

12. An integrated circuit according to claim 10, wherein the gate comprises at least partially silicided polycrystalline silicon.

13. An integrated circuit according to claim 10, wherein the gate comprises a metal, the semiconductor device further comprising a polycrystalline silicon layer covering the metal.

14. An integrated circuit to claim 11, comprising a first functional block comprising the semiconductor device and a second functional block comprising a further semiconductor device controlled by a further gate, wherein the further gate has a different effective work function than the gate.

15. An electronic device comprising an integrated circuit according to claim 10.
